(19) United States
(12) Patent Application Publication
(10) Pub. No.: US 2023/0185998 A1
(43) Pub. Date: Jun. 15, 2023

(54) SYSTEM AND METHOD FOR AI-ASSISTED SYSTEM DESIGN

(71) Applicant: Palo Alto Research Center Incorporated, Palo Alto, CA (US)

(72) Inventors: Ion Matei, Mountain View, CA (US); Aleksandar B. Feldman, Santa Cruz, CA (US); Johan de Kleer, Los Altos, CA (US)

(73) Assignee: Palo Alto Research Center Incorporated, Palo Alto, CA (US)

(21) Appl. No.: 17/552,132

(22) Filed: Dec. 15, 2021

(51) Int. Cl. G06F 30/27; G06N 3/04

(52) U.S. Cl. CPC G06F 30/27; G06N 3/0454

(57) ABSTRACT

Embodiments described herein provide a parameter manager for determining system parameters. During operation, the parameter manager can determine a set of parameters for generating a distribution of feasible parameters needed for designing a system. The parameter manager can map, using a hybrid generator of an artificial intelligence (AI) model, input samples from a predetermined distribution to a set of parameters. The parameter manager can then generate, using the mapping, a set of parameter samples corresponding to the set of parameters from the predetermined distribution. The parameter manager can also generate, using a physical model of the system in the hybrid generator, a set of outputs of the system induced by the set of parameter samples. The parameter manager can iteratively update the hybrid generator until the set of outputs follow an expected output of the system, thereby ensuring feasibility for the set of parameter samples.

### BACKGROUND

### Field

This disclosure is generally related to the field of artificial intelligence (AI). More specifically, this disclosure is related to a system and method for determining parameter space for designing a system using an enhanced generative adversarial network (GAN).

### Related Art

The exponential growth of AI-based techniques, such as neural networks, has made them a popular medium for generating synthetic data used in various applications. Generative adversarial networks (GANs) have become popular for generating synthetic data, such as synthetic but realistic images. To do so, a GAN typically includes a neural generator network, which is referred to as a generator, and a discriminator neural network, which is referred to as a discriminator.

The generator may produce data samples (e.g., a synthetic image) as outputs. The generator can attempt to improve the quality of the data samples by “convincing” the discriminator that these samples are real data samples (e.g., a real image). The discriminator is tasked with distinguishing data samples from the generated data samples. The discriminator can then determine whether a generated data sample conforms to the expected properties of a real data sample. As a result, through multiple iterations, the generator learns to generate data samples that incorporate the statistical properties of real samples.

While GANs can bring many desirable features to sample generation, some issues remain unsolved in the efficient exploration of parameter space for designing a system.

### SUMMARY

Embodiments described herein provide a parameter manager for determining system parameters. During operation, the parameter manager can determine a set of parameters for generating a distribution of feasible parameters needed for designing a system. The parameter manager can map, using a hybrid generator of an artificial intelligence (AI) model, input samples from a predetermined distribution to a set of parameters. The parameter manager can then generate, using the mapping, a set of parameter samples corresponding to the set of parameters from the predetermined distribution. The parameter manager can also generate, using a physical model of the system in the hybrid generator, a set of outputs of the system induced by the set of parameter samples. The parameter manager can iteratively update the hybrid generator until the set of outputs follow an expected output of the system, thereby ensuring feasibility for the set of parameter samples.

In a variation on this embodiment, the parameter manager can determine a set of approximation points for the hybrid generator and generate the set of parameter samples based on the set of approximation points.

In a variation on this embodiment, the parameter manager can classify, using a discriminator of the AI model, whether the set of parameter samples is generated from the predetermined distribution or a data distribution of the system. The parameter manager can then iteratively update the discriminator until the discriminator correctly classifies the set of parameter samples.

In a further variation, the parameter manager can determine, using the discriminator, a distribution of parameters. The distribution of parameters can produce an output from the physical model within a predetermined margin of the expected output of the system.

In a further variation, the data distribution of the system includes a combination of a distribution of the expected output of the system and a noise distribution representing the predetermined margin.

In a further variation wherein the AI model includes a generative adversarial network (GAN), and wherein the GAN is formed using the hybrid generator and the discriminator.

In a variation on this embodiment, iteratively updating the hybrid generator can include applying a gradient update scheme to the mapping.

In a variation on this embodiment, the parameter manager can determine a subset of parameters from the rest of the set of parameters and exclude the subset of parameters from the mapping.

In a variation on this embodiment, the parameter manager can determine the set of parameters based on a design architecture of the system.

### BRIEF DESCRIPTION OF THE FIGURES

FIG. 1A illustrates an exemplary parameter manager facilitating AI-assisted system design, in accordance with an embodiment of the present application.

FIG. 1B illustrates an exemplary hybrid generator for determining design parameters for a system, in accordance with an embodiment of the present application.

FIG. 2A presents a flowchart illustrating a method of a parameter manager determining design parameters for a system using a hybrid generator, in accordance with an embodiment of the present application.

FIG. 2B presents a flowchart illustrating a method of a parameter manager determining design parameters for a system using a hybrid generator on approximation points, in accordance with an embodiment of the present application.

FIG. 3 illustrates an exemplary GAN for determining design parameters for a system, in accordance with an embodiment of the present application.

FIG. 4 presents a flowchart illustrating a method of a parameter manager determining design parameters for a system using an enhanced GAN, in accordance with an embodiment of the present application.

FIG. 5 illustrates exemplary manifold learning for efficiently determining design parameters for a system using a hybrid generator, in accordance with an embodiment of the present application.

FIG. 6 illustrates an exemplary computer system that facilitates AI-assisted system design, in accordance with an embodiment of the present application.

FIG. 7 illustrates an exemplary apparatus that facilitates AI-assisted system design, in accordance with an embodiment of the present application.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the embodiments described herein are not limited to the embodiments shown, but are to be accorded the widest scope consistent with the principles and features disclosed herein.

### Overview

The embodiments described herein solve the problem of efficiently providing a large parameter space for designing a system by (i) determining feasible parameters of the system by mapping random noise to the parameters; and (ii) enhancing the feasible parameter space to conform to an expected output of the system. The system may use one or more components of a generative adversarial network (GAN) to generate the parameters.

Typically, designing a physical system can involve selecting system parameters for a given system architecture (e.g., the design of an electrical circuit) so that a set of performance metrics are satisfied. In other words, the system parameters are selected in such a way that a system produced using the parameters produces expected sets of output. Such parameters can be referred to as feasible parameters. For example, if the system is a low-pass filter, the corresponding system architecture can be the circuit design of the filter. Accordingly, the system parameters can include the respective units of resistors and capacitors needed for the circuit design. If the feasible units are selected, the resultant filter may produce the expected filter response.

With existing technologies, different optimization-based techniques are used to determine the feasible parameters for designing a system. However, the optimization-based approaches typically depend on the initial values of the optimization variables. As a result, exploration of the parameter space, which can indicate the range of plausible parameter values (e.g., non-negative values for resistance), using optimization-based techniques may require repeatedly initializing the technique and finding the solution. The repetitive nature of such a process can be error-prone and provide a limited feasible parameter space.

To solve this problem, embodiments described herein provide an efficient parameter manager that determines distributions of feasible parameters for designing a system. The parameter manager can use a generator that can map random noise to the system parameters. The generator can obtain samples from a known noise distribution (e.g., Gaussian distribution). The system parameters can be the parameters associated with the components needed to design the system. The parameter manager can update the generator using a gradient-based scheme until the system parameters become feasible.

A system designed with feasible system parameters can conform to the expected output of the system. As a result, the resultant parameter space can facilitate a number of possible design choices without relying on an initial set of parameter values. In addition to the feasible system parameters conforming to the expected output of the system, the parameter space can support additional design constraints, such as space and cost. The parameter manager may incorporate the additional design constraints into the mapping for the generator. Consequently, the generator can ensure that the feasible parameter space is further bounded by the additional design constraints.

The generator may include multiple models, thereby forming a hybrid structure. The hybrid generator can include an AI model (e.g., a neural network representing a generator) that can map the random noise generated from the noise distribution to corresponding system parameters. The hybrid generator can also include a physical model, such as a physics-based model, that can be based on the physical properties of the system and generate an output (e.g., the performance metrics) of the system. The physical model can ensure that an output of the system based on the generated system parameters is within an expected level (e.g., within a threshold). Hence, the system output of the hybrid generator can provide the system parameters that conform to the expected output of the system according to the physical model. Based on the system output, the gradient-based scheme can update the generator until the generated system parameters become feasible.

The parameter manager can also incorporate uncertainty in the output samples indicated by the physical model. Under such circumstances, the parameter manager can include a generative adversarial network (GAN). The GAN can include the hybrid generator and a discriminator. The generator of the hybrid generator and the discriminator can be updated until the output of the system induced by the system parameters produced by the generator can follow a distribution of the output of the system. In this way, the GAN can ensure that the output of the system based on the feasible parameter space corresponds to the distribution of the output of the system.

### Exemplary Parameter Manager

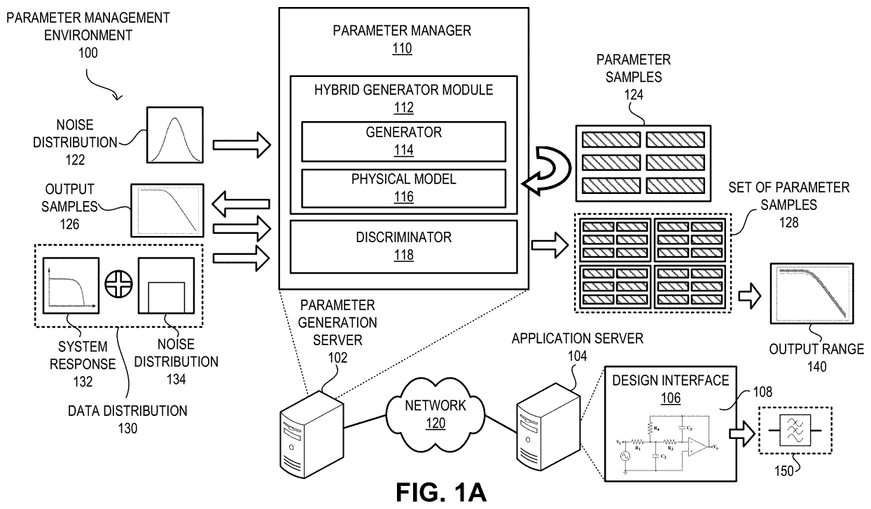

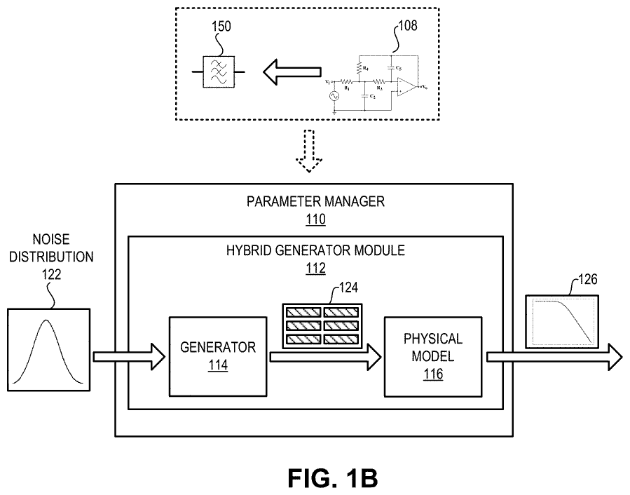

FIG. 1A illustrates an exemplary parameter manager facilitating AI-assisted system design, in accordance with an embodiment of the present application. In this example, a parameter management environment 100 includes an application server 104, which can host one or more applications that may be used for designing a system. Such an application may be equipped with a design interface 106 that can be used for designing a system. For example, the application can be a circuit design application, and interface 106 can be a circuit design interface that can allow a user to select different circuit components based on the corresponding system architecture 108. However, the corresponding design parameters are needed to select the components. A parameter generation server 102 of environment 100 can generate the design parameters and provide the design parameters to application server 104. Parameter generation server 102 can communicate with application server 104 via a network 120, which can be a local or a wide area network.

However, parameter generation server 102 may need to select the system parameters based on system architecture 108 so that a set of performance metrics are satisfied. In other words, the system parameters are selected in such a way that a system 150 produced using the parameters generates expected sets of output. For example, if system 150 is a low-pass filter, system architecture 108 can be the circuit design of the filter. Accordingly, the system parameters can include the respective input/output units of resistors and capacitors needed for the circuit design of system architecture 108. If the feasible units are selected, the resultant filter of system 150 may produce the expected filter response.

With existing technologies, parameter generation server 102 may use different optimization-based techniques to determine the feasible parameters for system architecture 108. However, the optimization-based approaches typically depend on the initial values of the optimization variables. As a result, exploration of the parameter space, which can indicate the range of plausible parameter values (e.g., non-negative values for resistance), using optimization-based techniques may require repeatedly initializing the technique and finding the solution. Such a process can strain the computing resources of parameter generation server 102. Furthermore, the repetitive nature of such a process can be error-prone and provide a limited feasible parameter space for system architecture 108.

If system 150 is a first-order filter with a target amplitude response, there can be a large variety of options for system architecture 108. Suppose that system architecture 108 is based on an RC circuit with a transfer function given by

$${V}_{out} = \frac{1}{1 + sRC} {V}_{in} .$$

Here, Vᵢₙ anti Vₒᵤₜ can be the input and output voltages, respectively. The corresponding amplitude response in decibels can be A(ω)=|H(jω)|=10 log₁₀ (1+ω²R²C²), which can show that the tunable quantity is the RC product. An optimization-based approach can be used to generate the parameters R and C. Accordingly, the optimization problem can be

$${min}_{R > 0 , C > 0} {\sum }_{i = 1}^{N} {‖ A ( {ω}_{i} ) - \hat{A} ( {ω}_{i} ) ‖}^{2}$$

for some relevant set of discrete frequencies ωᵢ. However, there could be a large number of possible solutions since any combination of R and C that can generate the optimal RC can be a solution.

Repeatedly solving the optimization problem with different initial conditions is inefficient, and determining how many initial conditions are necessary to determine the dependency between parameters is non-deterministic. An alternative approach to solving multiple optimization problems can be based on assuming that parameters R and C belong to some “optimal” but unknown probability distribution function. Let ƒ(r, c; β) be the distribution function of R, C parameterized by a vector of parameters β that minimizes the loss function

$${min}_{β} {\sum }_{i = 1}^{N} 𝔼 [ {‖ A ( {ω}_{i} ) - \hat{A} ( {ω}_{i} ) ‖}^{2} ] ,$$

where the expectation is taken with respect to the probability density function ƒ(r, c; β). However, parameter generation server 102 may not be able to solve the closed form of the expectation operation and may need to use samples from the current estimate of the probability density, the approximate the expectation. However, parameter generation server 102 may not use gradient-based algorithms when the number of optimization parameters is large.

To solve this problem, parameter generation server 102 can host a parameter manager 110 that can determine distributions of feasible parameters for designing a system. For example, parameter manager 110 can determine the distribution of feasible parameters based on system architecture 108. Parameter manager 110 can include a hybrid generator module 112 that can map random noise to system parameter samples 124. Hybrid generator module 112 can obtain samples from a known noise distribution 122 (e.g., Gaussian distribution). Here, parameter samples 124 can be associated with the components needed to design system 150 based on system architecture 108.

Hybrid generator module 112 may include multiple models, thereby forming the hybrid structure. Hybrid generator module 112 can include a generator 114, which can be a neural network representing a generator of a GAN. Generator 114 can map the random noise generated from noise distribution 122 to corresponding parameter samples 124. Hybrid generator module 112 can also include a physical model 116 that can be based on the physical properties of system 150 and produce output samples 126 (e.g., the performance metrics) of system 150. Physical model 116 can model the behavior of system 150 and ensure that output samples 126 produced based on parameter samples 124 is within an expected level (e.g., within a threshold).

Therefore, hybrid generator module 112 can be composed of two serial models. The first model can be generator 114 that transforms samples of noise distribution 122 into parameter samples 124. The second model can be physical model 116 that can use parameter samples 124 to produce output samples 126, which can be representative of the output of system 150. Based on output samples 126, parameter manager 110 can update generator 114 using a gradient-based scheme until parameter samples 124 become feasible. Hence, generator module 112 can use sampling from noise distribution 122 in combination with a stochastic gradient descent algorithm to ensure the feasibility of parameter samples 124.

Consequently, if system 150 is designed with the feasible parameter samples 124 based on system architecture 108, the output of system 150 can conform to the expected output of system 150. As a result, the parameter space corresponding to parameter samples 124 can facilitate a number of possible design choices without relying on an initial set of parameter values. In addition to the feasible parameter samples 124, the feasible parameter space can support additional design constraints, such as space and cost. Parameter manager 110 may incorporate the additional design constraints into the mapping of generator 112. Consequently, generator 112 can ensure that parameter samples 124 are further bounded by the additional design constraints.

Parameter manager 110 can also incorporate uncertainty in the output samples 126 indicated by physical model 116. Under such circumstances, parameter manager 110 can include a GAN. The GAN can include hybrid generator 112 and a discriminator 118. Generator 114 of hybrid generator 112 and discriminator 118 can be updated until an output of system 150 induced by parameter samples 124 can remain within a data distribution 130. Data distribution 130 can include a system response 132, which can be a distribution of outputs of system 150, and a noise distribution 134, which can be a uniform distribution in a prescribed tolerance interval. A sample from data distribution 130 can be a combination of an output value from system response 132 at the sample point (e.g., an amplitude response if system 150 is a filter) and a noise sample from noise distribution 134.

In an adversarial framework, discriminator 118 can learn to distinguish whether output samples 124 follows system response 132 within the tolerance range. Through the iterative learning of the GAN, generator 114 can generate a set of parameter samples 128. Each element of set 128 can be parameter samples that can remain within a prescribed tolerance of system response 132. Consequently, set of parameter samples 128 can produce an output range 140 for system 150, thereby presenting a user with a number of possible choices to design system 150 based on system architecture 108. In other words, output range 140 induced by set of parameter samples 128 produced by generator 114 can follow a distribution of outputs of system 150.

### Generator-Based Parameter Exploration

FIG. 1B illustrates an exemplary hybrid generator for determining design parameters for a system, in accordance with an embodiment of the present application. During operation, parameter manager 110 can determine a distribution of system parameters that minimizes a performance metric. Parameter manager 110 may use a probabilistic function, and represent a system parameter vector w as a random vector drawn from an unknown probability distribution that parameter manager 110 may determine. Upon learning the distribution, parameter manager 110 can sample from the distribution and generate the sets of parameter samples.

If system 150 is a filter and system architecture 108 corresponds to a filter design, parameter manager 110 may minimize:

$$min {𝔼}_{w \sim ℙ ( w )} [ {\sum }_{i = 1}^{N} {‖ A ( {ω}_{i} ) - \hat{A} ( {ω}_{i} ; w ) ‖}^{2} ] ,$$

where w is a vector of system parameters. Since [symbol] (w) is unknown, parameter manager 110 may obtain the samples from a known distribution. In particular, generator 114 can use a map w=G (z; β) that maps a random noise z with a known noise distribution 122 to the vector of parameters w. For example, generator 114 can obtain parameter samples 124, which can correspond to w, based on w=G(z; β). Generator 114 can then provide w physical model 116.

Upon obtaining w, physical model 116 can generate a corresponding output sample x_{g}=[Â(ω₀), . . . , Â(ω_{N})] corresponding to output samples 126. Consequently, the corresponding optimization problem can become

$${min}_{β} {𝔼}_{z \sim ℙ ( z )} [ 𝒥 ( z ; β ) ] ,$$

where the loss function is:

$$𝒥 ( z ; β ) = {\sum }_{i = 1}^{N} {‖ A ( {ω}_{i} ) - \hat{A} ( {ω}_{i} ; G ( z ; β ) ) ‖}^{2} .$$

Here, the optimization can be performed with respect to the parameters β of the map w=G (z; β). Parameter manager 110 may use a sampling-based solution approach in combination with a stochastic gradient descent algorithm to solve the optimization problem where g_{β} can be the approximation of the gradient of the loss function corresponding to batch i. Furthermore, a gradient update scheme, β←β+αg_{β}, can be the correction applied to the current minimizer estimate β that can depend on the choice of gradient-based algorithm. Examples of a gradient-based algorithm can include, but are not limited to, stochastic gradient descent, RMSProp, and Adam.

Parameter manager 110 may reduce the computational load by approximating the expectation operation using quadrature rules. For a scalar, standard Gaussian noise, given a budget of n approximation points, the expectation of the loss function can be approximated as

$$𝔼 [ 𝒥 ( z ; β ) ] \approx \frac{1}{\sqrt{π}} {\sum }_{i = 1}^{n} {w}_{i} 𝒥 ( \sqrt{2} {z}_{i} ) ,$$

where zᵢ are the roots of the physicists' version of the Hermite polynomials Hₙ(z). The associated weights can be determined by

$${w}_{i} = \frac{{2}^{n - 1} n ! \sqrt{π}}{{n}^{2} {{H}_{n - 1} ( {z}_{i} )}^{2}} .$$

For vector values of random Gaussian noise with independent entries, parameter manager 110 can use an approximation approach. Parameter manager 110 can obtain the weights using Cartesian products of the weights correspondent to scalar Gaussian random variables wᵢ=wᵢ_{₁} wᵢ_{₂} . . . wᵢ_{ₚ}, wherein iⱼ∈{1, 2, . . . , n}. Here, p can be the dimension of the noise vector. This results in a total of M=n^{p} number of weights and corresponding points zᵢ. Alternatively, parameter manager 110 may use sampling techniques based on sparse grids to deal with the increase in memory complexity for a large p. If M is too large to accommodate all quadrature points in the memory, parameter manager 110 may compute the gradient in batches followed by an update of vector β.

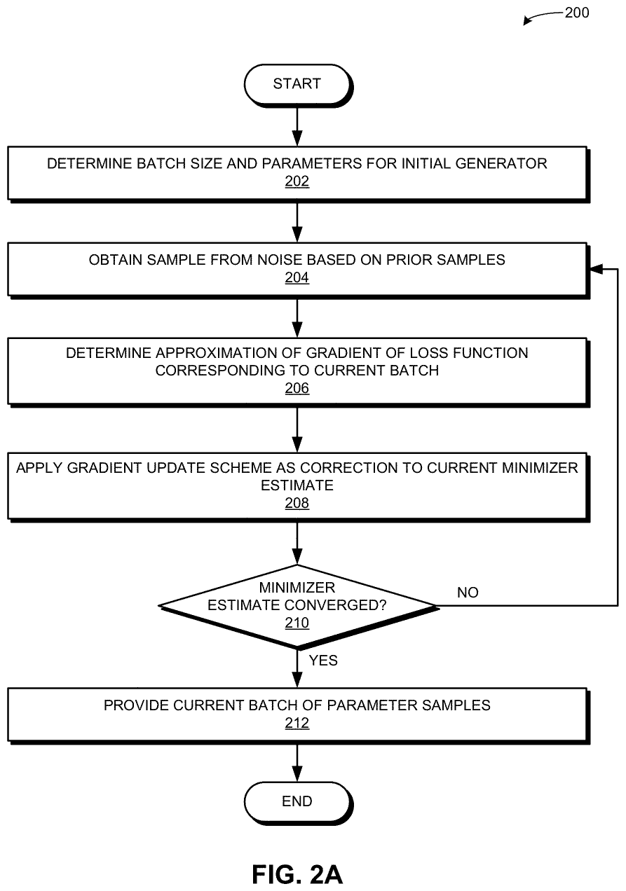

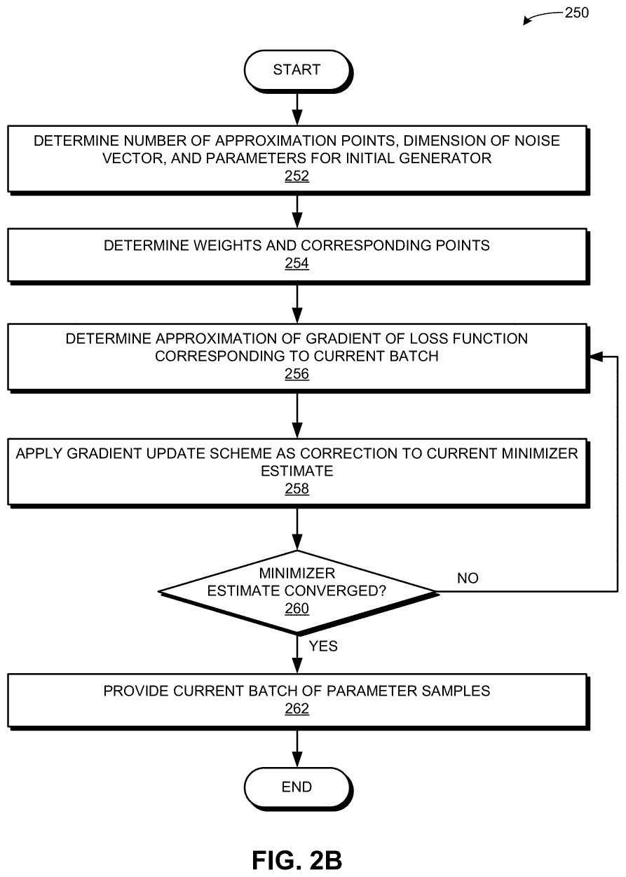

FIG. 2A presents a flowchart 200 illustrating a method of a parameter manager determining design parameters for a system using a hybrid generator, in accordance with an embodiment of the present application. During operation, the parameter manager can determine the batch size and the parameters for the initial generator (operation 202). For example, m can be the batch size and β₀ can be the parameters for the initial generator. The parameter manager can obtain the sample from the noise based on the prior samples (operation 204). The parameter manager can sample {z⁽ⁱ⁾}ᵢ₌₁^{m}˜ [symbol] (z) as a batch of prior samples. The parameter manager can determine an approximation of the gradient of loss function corresponding to the current batch (operation 206). Here,

$${g}_{β} ← {∇}_{β} [ \frac{1}{m} {Σ}_{i = 1}^{m} 𝒥 ( {z}^{( i )} ; β ) ]$$

can be the approximation.

The parameter manager can then apply a gradient update scheme as the correction to the current minimizer estimate (e.g., β←β+αg_{β}) (operation 208). Subsequently, the parameter manager can determine whether the minimizer estimate, β, has converged (operation 210). If the minimizer estimate has not converged, the parameter manager can continue to obtain the sample from the noise based on the prior samples (operation 204). On the other hand, if the minimizer estimate has converged, the parameter manager can provide the current batch of parameter samples (operation 212).

FIG. 2B presents a flowchart 250 illustrating a method of a parameter manager determining design parameters for a system using a hybrid generator on approximation points, in accordance with an embodiment of the present application. During operation, the parameter manager can determine the number of approximation points, the dimension of the noise vector, and the parameters for the initial generator (operation 252). For example, n can be the number of scalar approximation points, p can be the dimension of the noise vector, and β₀ can be the parameters for the initial generator. The parameter manager can determine the weights and the corresponding points (operation 254). For example, the parameter manager may compute the M=n^{p} quadrature weights wᵢ and corresponding points zᵢ using Hermite polynomials.

The parameter manager can determine an approximation of the gradient of loss function corresponding to the current batch (operation 256). Here, g_{β}←∇_{β}[Σᵢ₌₁^{M} wᵢ [symbol] (z⁽ⁱ⁾; β)] can be the approximation. The parameter manager can then apply a gradient update scheme as the correction to the current minimizer estimate (e.g., β←β+αg_{β}) (operation 258). Subsequently, the parameter manager can determine whether the minimizer estimate, β, has converged (operation 260). If the minimizer estimate has not converged, the parameter manager can continue to determine an approximation of the gradient of loss function corresponding to the current batch (operation 256). On the other hand, if the minimizer estimate has converged, the parameter manager can provide the current batch of parameter samples (operation 262).

### GAN-Based Parameter Exploration

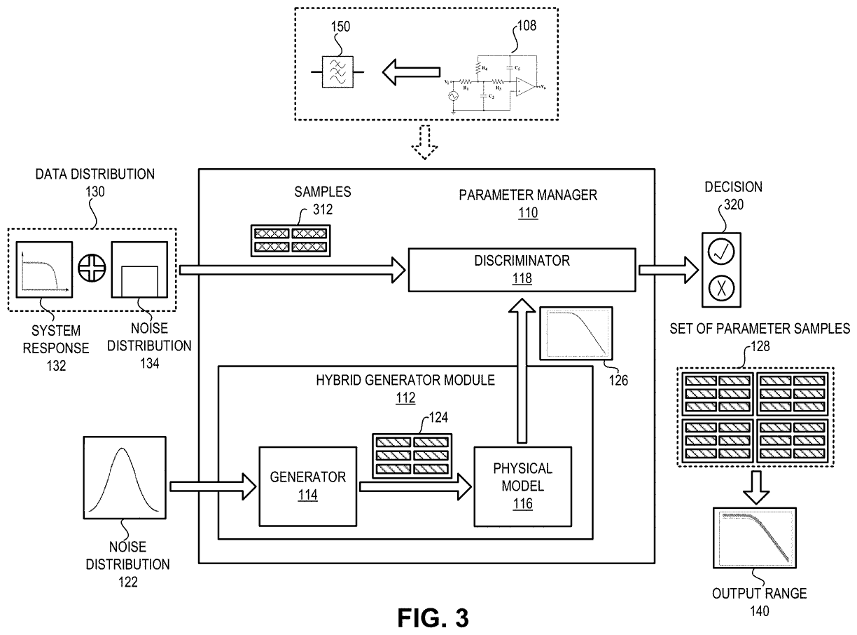

By using a GAN, parameter manager 110 can determine distributions of system parameters for system 150. For example, if system 150 is a filter, parameter manager 110 can ensure that the amplitude response satisfies |A(ω)|≤α for all ω and for some positive scalar α. Accordingly, parameter manager 110 can determine the feasible system parameters for designing a filter response that stays within a prescribed tolerance α. FIG. 3 illustrates an exemplary GAN for determining design parameters for a system, in accordance with an embodiment of the present application. Parameter manager 110 can then operate in an adversarial framework where a hybrid generator 112 competes against a discriminator 118 that can facilitate classification 320 for output samples from hybrid generator 112 as being from noise distribution 122 or data distribution 130.

Samples from data distribution 130, such as sample 312, can be expressed as x=[x₁, . . . , x_{N}], where xᵢ=Ā(ωᵢ)+v. Here, Ā(ωᵢ) can be a value of system response 132 (e.g., the amplitude response of a filter) at ωᵢ, and v can be a random noise from noise distribution 134. Noise distribution 134 can be uniformly distributed in the interval [−α, α] (i.e., v˜ [symbol] (−α, α)). Hybrid generator module 112 can include generator 114 that can transform samples of a random noise sample z from noise distribution 122 into parameter samples 124. Hybrid generator module 112 can include also include a physical model 116 that receives parameter samples 124 and produces corresponding output samples 126. For example, sample z can be mapped by a function G (z; β) into a vector of parameters w, which can correspond to parameter samples 124.

The parameter vector w can be provided to physical model 116 and used to generate the system response x_{g}=(Â_{g}(ωᵢ; G(z; β)))ᵢ. This process can induce a probability distribution [symbol] (x_{g}) at the output of hybrid generator 112. In the adversarial context of hybrid generator 112, the objective can be optimizing a two-player min-max game with a value function V (D, G), which can be

$${min}_{G} {max}_{D} V ( D , G ) = {𝔼}_{x \sim ℙ ( x )} [ log D ( x ) ] + {𝔼}_{z \sim ℙ ( z )} [ log ( 1 - D ( G ( z ) ) ) ] .$$

The optimal solution can be achieved when the data distribution is the same and the distribution of the samples degenerated by hybrid generator 112 (i.e., [symbol] (x)= [symbol] (x_{g})), and discriminator 118 can be represented by D*(x)=½.

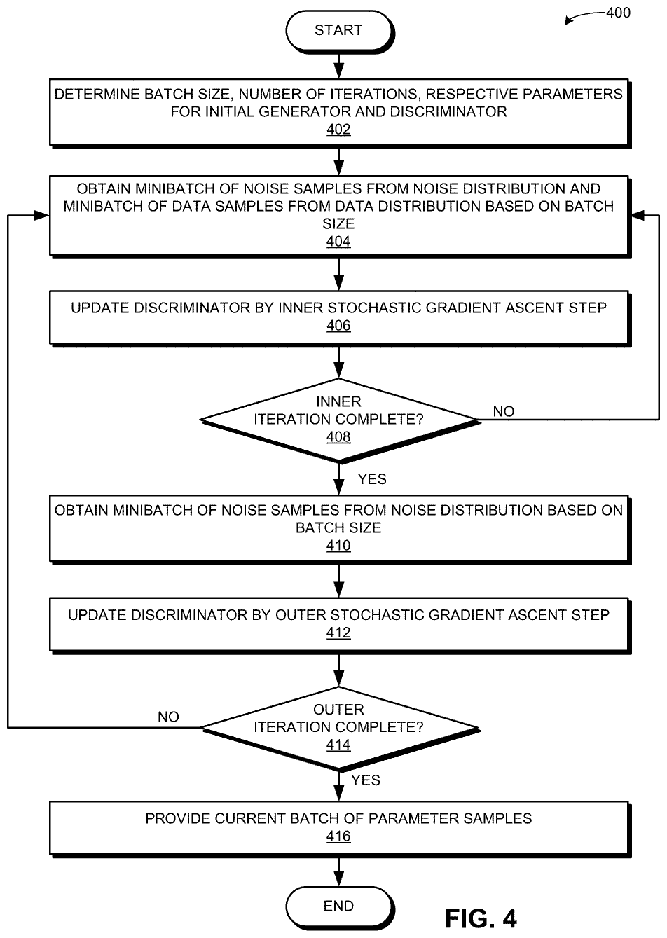

Parameter manager 110 can be trained based on the standard minibatch stochastic gradient descent GAN training algorithm. FIG. 4 presents a flowchart 400 illustrating a method of a parameter manager determining design parameters for a system using an enhanced GAN, in accordance with an embodiment of the present application. During operation, the parameter manager can determine the batch size, the number of iterations, respective parameters for the initial generator and discriminator (operation 402). Here, the batch size can be m, the number of outer iterations can be n, and the number of inner loop iterations can be k. Furthermore, β_{g}(0) and β_{d}(0) can be the parameters for the initial generator and discriminator, respectively.

The parameter manager can obtain the minibatch of noise samples from the noise distribution and the minibatch of samples from the data distribution based on the batch size (operation 404). For example, the parameter manager can sample minibatch of m noise samples {z⁽ⁱ⁾}ᵢ₌₁^{m} from distribution [symbol] (z), and sample minibatch of m noise samples {x⁽ⁱ⁾}ᵢ₌₁^{m} from distribution [symbol] (x). The parameter manager can then update the discriminator by the inner stochastic gradient ascent step (operation 406). The inner stochastic gradient ascent step can be

$${∇}_{{β}_{d}} \frac{1}{m} {\sum }_{i = 1}^{n} [ log D ( {x}^{( i )} ; {β}_{d} ) + log ( 1 - D ( G ( {z}^{( i )} ; {β}_{g} ) ; {β}_{d} ) ) ] .$$

The parameter manager can determine whether the inner iteration is complete (e.g., k iterations complete) (operation 408). If the inner iteration is not complete, the parameter manager can continue to obtain the data and noise samples (operation 404).

On the other hand, if the inner iteration is complete, the parameter manager can obtain the minibatch of noise samples from the noise distribution based on the batch size (operation 410). The parameter manager can then update the discriminator by the outer stochastic gradient ascent step (operation 412). This step can be

$${∇}_{{β}_{d}} \frac{1}{m} {\sum }_{i = 1}^{n} log ( 1 - D ( G ( {z}^{( i )} ; {β}_{g} ) ; {β}_{d} ) ) .$$

The parameter manager can determine whether the outer iteration is complete (e.g., n iterations complete) (operation 414). If the outer iteration is not complete, the parameter manager can continue to obtain the data and noise samples (operation 404). On the other hand, if the outer iteration is complete, the parameter manager can provide the current batch of parameter samples (operation 416).

### Manifold Learning

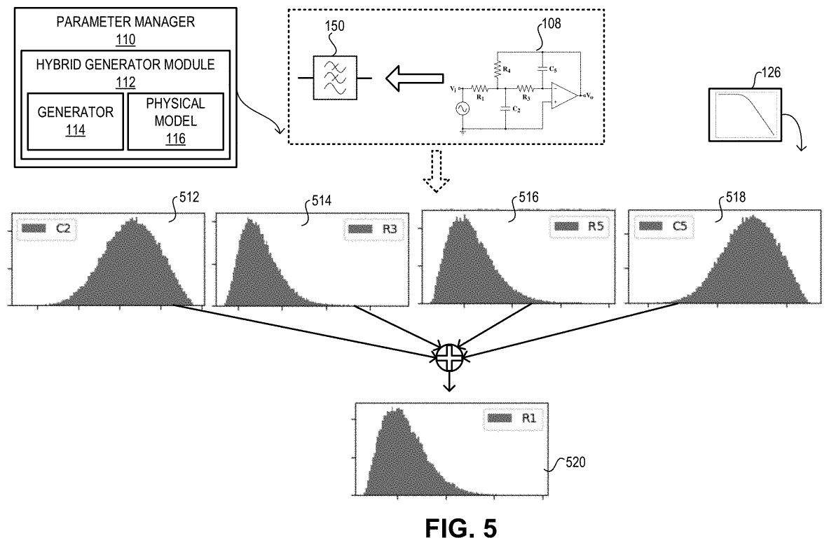

FIG. 5 illustrates exemplary manifold learning for efficiently determining design parameters for a system using a hybrid generator, in accordance with an embodiment of the present application. If system 150 is a low-pass filter based on system architecture 108, the transfer function can be

$$H ( s ) = \frac{1}{A {s}^{2} + B s + C} .$$

### Here,

$$A = {R}_{1} {R}_{3} {C}_{2} {C}_{5} , B = {R}_{3} {C}_{5} + {R}_{1} {C}_{5} + \frac{{R}_{1} {R}_{3} {C}_{5}}{{R}_{4}} , and C = \frac{{R}_{1}}{{R}_{4}} .$$

Hence, R₁, C₂, R₃, R₅, and C₅ can be the system parameters for system 150. The amplitude response for system 150 in dB can be indicated by A(ω)=−10 log [(Aω²−C)²+B²ω²]. The distributions 512, 514, 516, and 518, and 520 can be associated with the parameter samples of C₂, R₃, R₅, C₅, and R₁, respectively. Parameter manager 110 can determine whether there are correlations between the parameter samples.

This problem can be expressed as a manifold learning problem. The objective of the learning problem can be finding a nontrivial map ƒ(x)=0. Here, x can be a sample of system parameters belonging to a set χ. Map ƒ(x) can typically be represented in terms of a set of Kernel functions (or feature maps) ƒ(x)=Σᵢ₌₁ⁿ αᵢϕᵢ(x) with ϕᵢ: χ→ [symbol] , where [symbol] can be the feature space. When considering all samples, parameter manager 110 can determine the relation Mα=0, where the entries of matrix M is defined as (M)ᵢⱼ=(ϕᵢ(x^{(j)}))) with j denoting the jth sample of x. Solving Mα=0 can be equivalent to characterizing the nullspace of matrix M or matrix M^{T}M. A singular value decomposition (SVD) decomposition for matrix M can be used to obtain M=UΣV^{T}. Here, the columns of matrix V can correspond to the zero singular values are the basis of the nullspace of M.

Linear Kernel functions ϕᵢ(x)=xᵢ can be considered for executing the SVD decomposition for the samples of system parameters indicated in distributions 512, 514, 516, and 518, and 520. For this determination, any singular value smaller than 0.02 can be interpreted as a singular value of zero. Therefore, the column of matrix V that corresponds to the singular value of zero can define the nullspace of matrix M. In other words, parameter manager 110 can determine a relation x^{T} α=0, where the entries of x can correspond to parameters R₁, C₂, R₃, R₅, and C₅. Therefore, one of the parameters can be computed from the remaining four parameters. For example, parameter manager 110 can calculate

$${R}_{1} = - \frac{1}{{α}_{1}} ( {α}_{2} {C}_{2} + {α}_{3} {R}_{3} + {α}_{4} {R}_{5} + {α}_{5} {C}_{5} ) .$$

This linear relation can be validated by computing \hat{R}₁ based on respective samples from distributions 512, 514, 516, and 518, and comparing with distribution 520 of R₁. For subsequent computations, parameter manager 110 may use generator 112 to generate parameter samples for C₂, R₃, R₅, and C₅. Parameter manager 110 can then calculate R₁ from the other values. In this way, the manifold learning facilitates the reduction of the size of generator 112, thereby reducing the computing load associated with the execution of generator 112.

### Exemplary Computer System and Apparatus

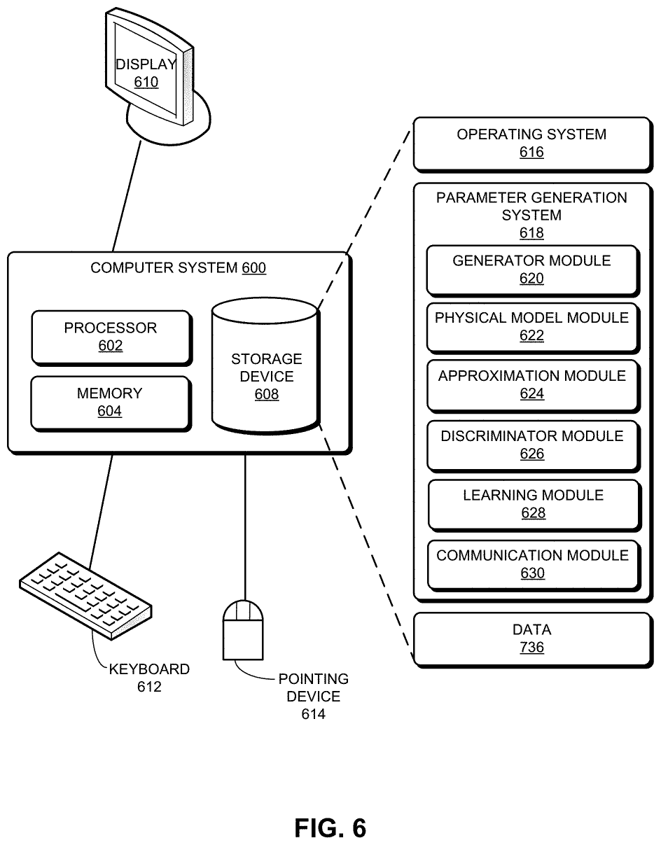

FIG. 6 illustrates an exemplary computer system that facilitates AI-assisted system design, in accordance with an embodiment of the present application. Computer system 600 includes a processor 602, a memory device 604, and a storage device 608. Memory device 604 can include a volatile memory device (e.g., a dual in-line memory module (DIMM)). Furthermore, computer system 600 can be coupled to a display device 610, a keyboard 612, and a pointing device 614. Storage device 608 can store an operating system 616, a parameter generation system 618, and data 636. Parameter generation system 618 can facilitate the operations of parameter manager 110.

Parameter generation system 618 can include instructions, which when executed by computer system 600 can cause computer system 600 to perform methods and/or processes described in this disclosure. Specifically, parameter generation system 618 can include instructions for mapping samples from a noise distribution to system parameter samples (generator module 620). Parameter generation system 618 can also include instructions for generating feasible parameter samples for a system (generator module 620).

Furthermore, parameter generation system 618 includes instructions for generating outputs (e.g., performance metrics) based on a physical model of a system based on generated parameter samples (physical model module 622). Generator module 620 and physical model module 622 can facilitate the operations of hybrid generator 112, as described in conjunction with FIG. 1A. Parameter generation system 618 can also include instructions for approximating the expectation operation based on a predetermined number of approximation points (e.g., based on Hermite polynomials Hₙ(z)) (approximation module 624).

Moreover, parameter generation system 618 can also include instructions for determining distributions of system parameters for a system such that the output of the system remains within a tolerance level (discriminator module 626). Parameter generation system 618 can further include instructions for classifying an output sample from a hybrid generator 112 as being from a noise distribution or a data distribution (discriminator module 626). Parameter generation system 618 can also include instructions for determining a parameter based on other parameters for a system (learning module 628).

Parameter generation system 618 may further include instructions for sending and receiving messages (communication module 628). Data 636 can include any data that can facilitate the operations of one or more of: hybrid generator module 112, generator module 114, physical model 116, and discriminator 118. Data 636 may include one or more of: information of a noise distribution and samples from the distribution, mapping information, output samples, information associated with the system response and corresponding noise distribution and set of parameter samples.

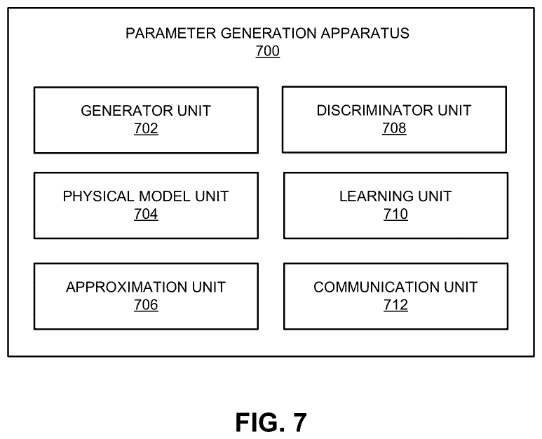

FIG. 7 illustrates an exemplary apparatus that facilitates AI-assisted system design, in accordance with an embodiment of the present application. Parameter generation apparatus 700 can comprise a plurality of units or apparatuses which may communicate with one another via a wired, wireless, quantum light, or electrical communication channel. Apparatus 700 may be realized using one or more integrated circuits, and may include fewer or more units or apparatuses than those shown in FIG. 7. Further, apparatus 700 may be integrated in a computer system, or realized as a separate device that is capable of communicating with other computer systems and/or devices. Specifically, apparatus 700 can comprise units 702-712, which perform functions or operations similar to modules 620-630 of computer system 600 of FIG. 6, including: a generator unit 702; a physical model unit 704; an approximation unit 706; a discriminator unit 708; a learning unit 710; and a communication unit 712.

The data structures and code described in this detailed description are typically stored on a computer-readable storage medium, which may be any device or medium that can store code and/or data for use by a computer system. The computer-readable storage medium includes, but is not limited to, volatile memory, non-volatile memory, magnetic and optical storage devices such as disks, magnetic tape, CDs (compact discs), DVDs (digital versatile discs or digital video discs), or other media capable of storing computer-readable media now known or later developed.

The methods and processes described in the detailed description section can be embodied as code and/or data, which can be stored in a computer-readable storage medium as described above. When a computer system reads and executes the code and/or data stored on the computer-readable storage medium, the computer system performs the methods and processes embodied as data structures and code and stored within the computer-readable storage medium.

Furthermore, the methods and processes described above can be included in hardware modules. For example, the hardware modules can include, but are not limited to, application-specific integrated circuit (ASIC) chips, field-programmable gate arrays (FPGAs), and other programmable-logic devices now known or later developed. When the hardware modules are activated, the hardware modules perform the methods and processes included within the hardware modules.

The foregoing embodiments described herein have been presented for purposes of illustration and description only. They are not intended to be exhaustive or to limit the embodiments described herein to the forms disclosed. Accordingly, many modifications and variations will be apparent to practitioners skilled in the art. Additionally, the above disclosure is not intended to limit the embodiments described herein. The scope of the embodiments described herein is defined by the appended claims.

What is claimed is:

1. A method for determining system parameters, the method comprising:
determining a set of parameters for generating a distribution of feasible parameters needed for designing a system;
mapping, using a hybrid generator of an artificial intelligence (AI) model, input samples from a predetermined distribution to a set of parameters;
generating, using the mapping, a set of parameter samples corresponding to the set of parameters from the predetermined distribution;
generating, using a physical model of the system in the hybrid generator, a set of outputs of the system induced by the set of parameter samples; and
iteratively updating the hybrid generator until the set of outputs follow an expected output of the system, thereby ensuring feasibility for the set of parameter samples.

2. The method of claim 1, further comprising:
determining a set of approximation points for the hybrid generator; and
generating the set of parameter samples based on the set of approximation points.

3. The method of claim 1, further comprising:
classifying, using a discriminator of the AI model, whether the set of parameter samples is generated from the predetermined distribution or a data distribution of the system; and
iteratively updating the discriminator until the discriminator correctly classifies the set of parameter samples.

4. The method of claim 3, further comprising determining, using the discriminator, a distribution of parameters, wherein samples from the distribution of parameters produce an output from the physical model within a predetermined margin of the expected output of the system.

5. The method of claim 4, wherein the data distribution of the system includes a combination of a distribution of the expected output of the system and a noise distribution representing the predetermined margin.

6. The method of claim 3, wherein the AI model includes a generative adversarial network (GAN), and wherein the GAN is formed using the hybrid generator and the discriminator.

7. The method of claim 1, wherein iteratively updating the hybrid generator further comprises applying a gradient update scheme to the mapping.

8. The method of claim 1, further comprising:
determining a subset of parameters from a rest of the set of parameters; and
excluding the subset of parameters from the mapping.

9. The method of claim 1, further comprising determining the set of parameters based on a design architecture of the system.

10. A non-transitory computer-readable storage medium storing instructions that when executed by a computer cause the computer to perform a method for determining system parameters, the method comprising:
determining a set of parameters for generating a distribution of feasible parameters needed for designing a system;
mapping, using a hybrid generator of an artificial intelligence (AI) model, input samples from a predetermined distribution to a set of parameters;
generating, using the mapping, a set of parameter samples corresponding to the set of parameters from the predetermined distribution;
generating, using a physical model of the system in the hybrid generator, a set of outputs of the system induced by the set of parameter samples; and
iteratively updating the hybrid generator until the set of outputs follow an expected output of the system, thereby ensuring feasibility for the set of parameter samples.

11. The non-transitory computer-readable storage medium of claim 10, wherein the method further comprises:
determining a set of approximation points for the hybrid generator; and
generating the set of parameter samples based on the set of approximation points.

12. The non-transitory computer-readable storage medium of claim 10, wherein the method further comprises:
classifying, using a discriminator of the AI model, whether the set of parameter samples is generated from the predetermined distribution or a data distribution of the system; and
iteratively updating the discriminator until the discriminator correctly classifies the set of parameter samples.

13. The non-transitory computer-readable storage medium of claim 12, wherein the method further comprises determining, using the discriminator, a distribution of parameters, wherein samples from the distribution of parameters produce an output from the physical model within a predetermined margin of the expected output of the system.

14. The non-transitory computer-readable storage medium of claim 13, wherein the data distribution of the system includes a combination of a distribution of the expected output of the system and a noise distribution representing the predetermined margin.

15. The non-transitory computer-readable storage medium of claim 12, wherein the AI model includes a generative adversarial network (GAN), and wherein the GAN is formed using the hybrid generator and the discriminator.

16. The non-transitory computer-readable storage medium of claim 10, wherein iteratively updating the hybrid generator further comprises applying a gradient update scheme to the mapping.

17. The non-transitory computer-readable storage medium of claim 10, wherein the method further comprises:
determining a subset of parameters from a rest of the set of parameters; and
excluding the subset of parameters from the mapping.

18. The non-transitory computer-readable storage medium of claim 10, wherein the method further comprises determining the set of parameters based on a design architecture of the system.

19. A computer system, comprising:
a storage device;
a processor;
a non-transitory computer-readable storage medium storing instructions, which when executed by the processor causes the processor to perform a method for determining system parameters, the method comprising:
determining a set of parameters for generating a distribution of feasible parameters needed for designing a system;
mapping, using a hybrid generator of an artificial intelligence (AI) model, input samples from a predetermined distribution to a set of parameters;
generating, using the mapping, a set of parameter samples corresponding to the set of parameters from the predetermined distribution;
generating, using a physical model of the system in the hybrid generator, a set of outputs of the system induced by the set of parameter samples; and
iteratively updating the hybrid generator until the set of outputs follow an expected output of the system, thereby ensuring feasibility for the set of parameter samples.

20. The computer system of claim 19, wherein the method further comprises:
classifying, using a discriminator of the AI model, whether the set of parameter samples is generated from the predetermined distribution or a data distribution of the system; and
iteratively updating the discriminator until the discriminator correctly classifies the set of parameter samples.
